(19) United States
(12) Patent Application Publication
(10) Pub. No.: US 2021/0225895 A1
(43) Pub. Date: Jul. 22, 2021

(54) DISPLAY PANEL AND MANUFACTURING METHOD THEREFOR

(71) Applicant: HKC Corporation Limited, SHENZHEN (CN)

(72) Inventor: BEI ZHOU HUANG, SHENZHEN (CN)

(21) Appl. No.: 16/313,136

(22) PCT Filed: Oct. 23, 2018
(86) PCT No.: PCT/CN2018/111309

§ 371 Date: Dec. 25, 2018

(30) Foreign Application Priority Data
Sep. 14, 2018 (CN) 201811071915.6

(51) Int. Cl. H01L 27/12

(52) U.S. Cl. CPC H01L 27/1244; H01L 27/1288

(57) ABSTRACT

This application discloses a display panel and a manufacturing method therefor. The display panel includes: a first substrate; a metal layer, the metal layer being arranged on the first substrate and the metal layer including an electrical contact area; and a protective layer, coveting the metal layer and keeping away from the electrical contact area.

This application claims priority to Chinese Patent Application No. CN 201811071915.6, filed with the Chinese Patent Office on Sep. 14, 2018 and entitled “DISPLAY PANEL AND MANUFACTURING METHOD THEREFOR”, which is incorporated herein by reference in its entirety.

### TECHNICAL FIELD

This application relates to the field of display technologies, and more specifically, to a display panel and a manufacturing method therefor.

### BACKGROUND

The description herein provides only background information related to this application, but does not necessarily constitute the existing technology.

Owing to many advantages such as thinness, power saving, and no radiation, liquid crystal displays are widely applied. Most liquid crystal displays on the market are backlight liquid crystal displays. The backlight liquid crystal display includes a liquid crystal panel and a backlight module. The working principle of the liquid crystal panel is: Liquid crystal molecules are placed between two parallel glass substrates and a drive voltage is applied across the two glass substrates to control rotating directions of the liquid crystal molecules, so that light in the backlight module is refracted out to generate an image.

A structure in which an electrode layer (ITO) and silver (Ag) are combined is usually used at an anode. A signal input conducting wire is usually made of aluminum. Patterns at the anode are usually etched by wet etching by using acid. Due to a difference in electric potential energy between Ag and Al, a chemical reaction Ag⁺+Al→Al⁺+Ag takes place in the acid. As a result, two ends of the aluminum (Al) conducting wire are corroded, and silver (Ag) is separated out.

Such a phenomenon is especially severe in an electrical contact area, and aluminum corrosion leads to an increase in the resistance of signal lines or disconnection of signal lines.

### SUMMARY

An objective of this application is to provide a display panel for preventing corrosion of an aluminum side surface and a manufacturing method therefor.

To achieve the foregoing objective, this application provides a display panel. A display panel, comprises:

a first substrate;

a metal layer, the metal layer being arranged on the first substrate;

the metal layer comprising an electrical contact area electrically connected to a corresponding conductive component; and

a protective layer, covering the metal layer and keeping away from the electrical contact area.

This application further discloses a display panel. A display panel. The display panel comprises: a first substrate, a metal layer, and a protective layer, wherein the metal layer, the metal layer is arranged on the first substrate; the metal layer comprises an electrical contact area electrically connected to a corresponding conductive component; the protective layer covers the metal layer and keeps away from the electrical contact area; the protective layer comprises a first protective layer and a second protective layer; the electrical contact area is provided on an upper surface of the metal layer, and the width of the electrical contact area is less than the width of the metal layer; and the first protective layer and the second protective layer are respectively arranged at two ends of the metal layer, and parts of the first protective layer and the second protective layer cover the upper surface of the metal layer and correspond to positions of the end parts of the metal layer. The protective layer and a planarizing layer are of a same material, and the metal layer comprises aluminum.

This application further discloses a method adapted to manufacture a display panel. A method adapted to manufacture a display panel comprises:

forming a metal layer on a first substrate; and

forming a protective layer on the metal layer, wherein

the metal layer comprises an electrical contact area electrically connected to a corresponding conductive component; and the protective layer keeps away from the electrical contact area.

Because of the protective layer is on the metal layer, when etching is performed at an anode, and the metal layer has a protective layer of a certain thickness for protection, the metal layer can be effectively prevented from being corroded, and corrosion occurring at the circuit is reduced, thereby avoiding an excessively large resistance, and avoiding a short circuit which causes disconnection and a decrease in display image quality. Because the protective layer covers a non-electrical contact area of the metal layer, an electrical connection effect of the metal layer is not affected.

### BRIEF DESCRIPTION OF DRAWINGS

The accompanying drawings comprised are used to provide a further understanding of the embodiments of this application. The accompanying drawings constitute a part of the specification, illustrate examples of implementations of this application, and explain the principle of this application together with the text description. Obviously, the accompanying drawings in the following description are merely some embodiments of this application. For a person of ordinary skill in the art, the person may obtain other drawings according to these accompanying drawings without creative effects. In the figures:

FIG. 1 is a schematic diagram of an entire structure according to an embodiment of this application;

FIG. 2 is a schematic diagram of an entire structure according to an embodiment of this application;

FIG. 3 is a schematic top view of a structure according to another embodiment of this application;

FIG. 4 is a schematic diagram of steps of a method according to another embodiment of this application; and

FIG. 5 is a schematic diagram of steps of a method according to another embodiment of this application.

### DETAILED DESCRIPTION

Specific structures and functional details disclosed herein are merely representative, and are intended to describe the objectives of the exemplary embodiments of this application. However, this application may be specifically implemented in many alternative forms, and should not be construed as being limited to the embodiments set forth herein.

In the description of this application, it should be understood that orientation or position relationships indicated by the terms such as “center”, “transverse”, “on”, “below”, “left”, “right”, “vertical”, “horizontal”, “top”, “bottom”, “inside”, and “outside” are based on orientation or position relationships shown in the accompanying drawings, and are used only for ease and brevity of illustration and description, rather than indicating or implying that the mentioned apparatus or component must have a particular orientation or must be constructed and operated in a particular orientation. Therefore, such terms should not be construed as limiting of this application. In addition, the terms such as “first” and “second” are used only for the purpose of description, and should not be understood as indicating or implying the relative importance or implicitly specifying the number of the indicated technical features. Therefore, a feature defined by “first” or “second” can explicitly or implicitly include one or more of said features. In the description of this application, unless otherwise stated, “a plurality of” means two or more than two. In addition, the terms “include”, “comprise” and any variant thereof are intended to cover non-exclusive inclusion.

In the description of this application, it should be noted that unless otherwise explicitly specified or defined, the terms such as “mount”, “install”, “connect”, and “connection” should be understood in a broad sense. For example, the connection may be a fixed connection, a detachable connection, or an integral connection; or the connection may be a mechanical connection or an electrical connection; or the connection may be a direct connection, an indirect connection through an intermediary, or internal communication between two components. Persons of ordinary skill in the art may understand the specific meanings of the foregoing terms in this application according to specific situations.

The terminology used herein is for the purpose of describing specific embodiments only and is not intended to be limiting of exemplary embodiments. As used herein, the singular forms “a”, “an” and “the” are intended to include the plural forms as well, unless the context clearly indicates otherwise. It should be further understood that the terms “include” and/or “comprise” when used in this specification, specify the presence of stated features, integers, steps, operations, elements, and/or components, but do not preclude the presence or addition of one or more other features, integers, steps, operations, elements, components, and/or combinations thereof.

The following further describes this application with reference to the accompanying drawings and optional embodiments.

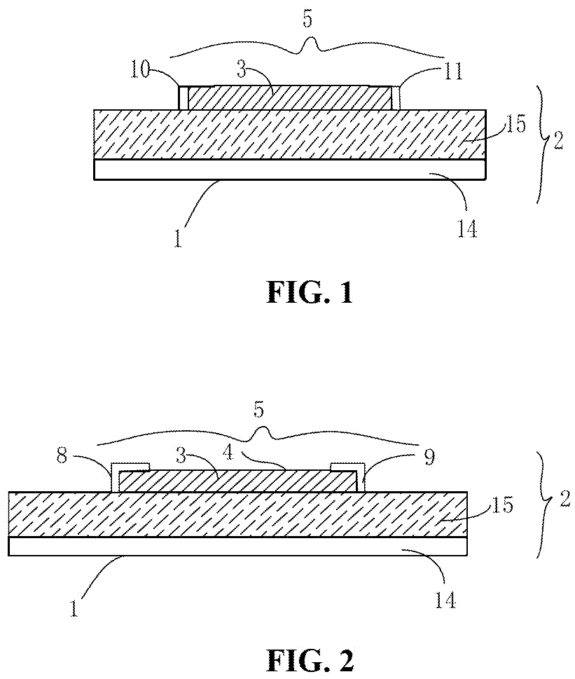

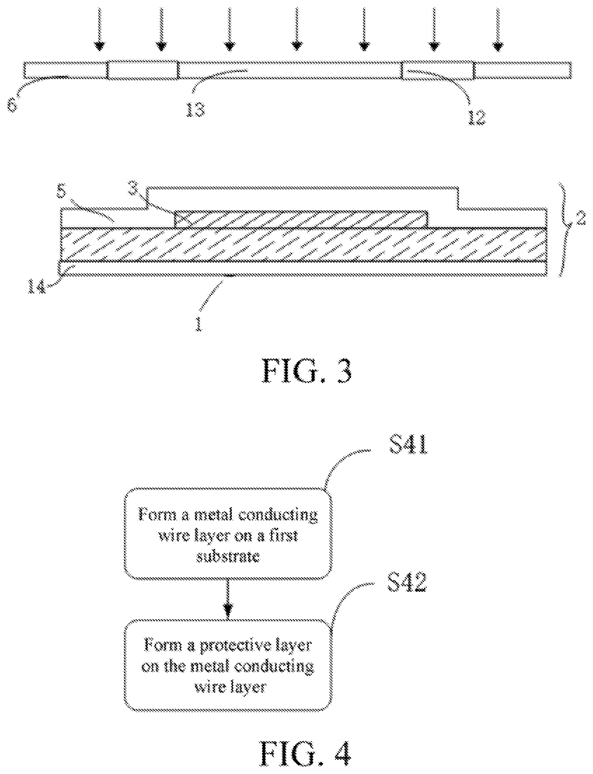

Referring to FIG. 1 to FIG. 3, an embodiment of this application discloses a display panel 1.

A first substrate 2, a metal layer 3, and a protective layer 5. The metal layer 3, the metal layer 3 is arranged on the first substrate 2; the metal layer 3 includes an electrical contact area 4 electrically connected to a corresponding conductive component; and the protective layer 5 covers the metal layer 3 and keeps away from the electrical contact area 4. The protective layer 5 includes a first protective layer 8 and a second protective layer 9. The electrical contact area 4 is provided on an upper surface of the metal layer 3, and the width of the electrical contact area 4 is less than the width of the metal layer 3; and the first protective layer 8 and the second protective layer 9 are respectively arranged at two ends of the metal layer 3, and parts of the first protective layer 8 and the second protective layer 9 cover the upper surface of the metal layer 3 and correspond to positions of the two end parts of the electrical contact area 4. The protective layer 5 and a planarizing layer are of a same material, and the metal layer includes aluminum.

In another embodiment of this application, referring to FIG. 1 to FIG. 5, a display panel 1 is disclosed.

The display panel 1 includes: a first substrate 2, a metal layer 3, and a protective layer 5. The metal layer 3, the metal layer 3 is arranged on the first substrate 2; the metal layer 3 includes an electrical contact area 4 electrically connected to a corresponding conductive component; and the protective layer 5 covers the metal layer 3 and keeps away from the electrical contact area 4.

The protective layer 5 is on the metal layer 3, so that when etching is performed at an anode, because the metal layer 3 has the protective layer 5 of a certain thickness for protection, the metal layer can be effectively prevented from being corroded, and corrosion occurring at the circuit is reduced, thereby avoiding an excessively large resistance, and avoiding a short circuit which causes disconnection and a decrease in display image quality. Because the protective layer 5 covers a non-electrical contact area 4 of the metal layer 3, an electrical connection effect of the metal layer 3 is not affected.

In this embodiment, optionally, the protective layer 5 includes a first protective layer 8 and a second protective layer 9.

The electrical contact area 4 is provided on an upper surface of the metal layer 3, and the width of the electrical contact area 4 is less than the width of the metal layer 3; the first protective layer 8 and the second protective layer 9 are respectively arranged at two ends of the metal layer 3, and parts of the first protective layer 8 and the second protective layer 9 cover the upper surface of the metal layer 3 and correspond to positions of the end parts of the electrical contact area 4.

Other than the electrical contact area 4, the exposed part of the metal layer 3 is fully protected.

In this embodiment, optionally, the protective layer 5 includes a third protective layer 10 and a fourth protective layer 11.

The electrical contact area 4 is provided on an upper surface of the metal layer 3, and the width of the electrical contact area 4 is less than the width of the metal layer 3; and the third protective layer 10 and the fourth protective layer 11 are respectively arranged on two ends of the metal layer 3.

Both ends of the metal layer 3 are covered, ensuring that the side surface is not corroded and ensuring a more thorough electrical connection to the electrical contact area 4, a more thorough electrical connection to the corresponding conductive component, and a better power-on effect.

In this embodiment, optionally; the protective layer 5 and the planarizing layer are of a same material, which has desirable texture and a certain thickness, to avoid corrosion of the protective layer 5. In addition, the thickness does not affect a contact effect on the surface of the electrically connected metal layer 3.

In this embodiment, optionally, the metal layer includes aluminum.

Aluminum has desirable conductive performance and low costs and is easy to manufacture. The metal layer may also be made of a material having desirable conductive performance such as copper and silver.

In another embodiment of this application, referring to FIG. 4, a method adapted to manufacture a display panel 1 is disclosed.

The method adapted to manufacture a display panel 1 includes:

S41: Form a metal layer on a first substrate 2.

S42: Form a protective layer 5 on the metal layer.

The metal layer 3 includes an electrical contact area 4 electrically connected to a corresponding conductive component; and the protective layer 5 keeps away from the electrical contact area 4.

The protective layer 5 is on the metal layer 3, so that when etching is performed at an anode, because the metal layer 3 has the protective layer 5 of a certain thickness for protection, the metal layer can be effectively prevented from being corroded, and corrosion occurring at the circuit is reduced, thereby avoiding an excessively large resistance, and avoiding a short circuit which causes disconnection and a decrease in display image quality. Because the protective layer 5 covers a non-electrical contact area 4 of the metal layer 3, an electrical connection effect of the metal layer 3 is not affected, a working procedure is saved, and the process is simple.

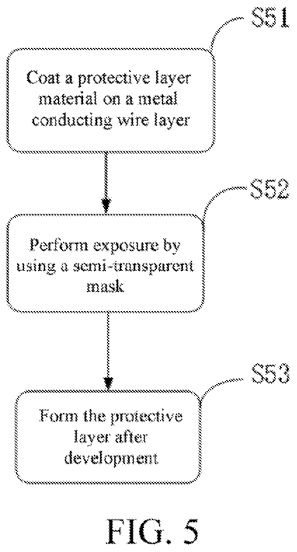

In an embodiment, optionally, refer to FIG. 5.

S51: Coat a protective layer 5 material on a metal layer in this embodiment.

S52: Expose an electrical contact area 4 and an area corresponding to the protective layer 5 by using a semi-transparent mask.

S53: Form the protective layer 5 after development.

The light transmittance of the semi-transparent mask corresponding to the electrical contact area 4 is greater than the light transmittance of an area corresponding protective layer 5. The semi-transparent mask includes: a fully transparent area 12, where the fully transparent area 12 corresponds to the electrical contact area 4 of the metal layer 3; and a semi-transparent area 12, where the semi-transparent area 12 and the fully transparent area 12 are in a same line, corresponding to the two end parts of the metal layer 3.

By means of position alignment, an area is selected for protection according to a priority, a manufacturing process is not added, and a protection scope is ensured, thereby providing more effective protection. When a manufacturing process is not added, a certain thickness can be reserved, so as to avoid a case of a short circuit due to corrosion of the side surface of the metal layer 3 when etching is performed, and ensure an electrical connection effect.

In this embodiment, optionally, the light transmittances of the two end parts of the electrical contact area 4 are 20% to 30%, and the light transmittance of the electrical contact area 4 is 100%.

It is ensured that after exposure development, the protective layer 5 at the two ends has a certain thickness at the two ends of the metal layer 3, so that when etching is performed, the metal layer is protected from being corroded by a marginal material, thereby avoiding an impact on the electrical contact area 4 which causes an increase in resistance and leads to a short circuit.

In this embodiment, optionally, the protection layer 5 includes a first protection layer 8 and a second protection layer 95.

The electrical contact area 4 is provided on an upper surface of the metal layer 3, and the width of the electrical contact area 4 is less than the width of the metal layer 3; and the first protection layer 8 and the second protection layer 9 are respectively arranged on two ends of the metal layer 3 and at positions of two end parts of the metal layer 3.

Other than the position corresponding to the electrical contact area 4, the exposed part of the metal layer 3 is fully protected.

The panel of this application may be a twisted nematic (TN) panel, an in-plane switching (IPS) panel, or a multi-domain vertical alignment (VA) panel, and may certainly be any other suitable type of panel.

The foregoing contents are further detailed descriptions of this application in conjunction with specific optional embodiments, and it should not be considered that the specific implementation of this application is limited to these descriptions. Persons of ordinary skill in the art can further make simple deductions or replacements without departing from the concept of this application, and such deductions or replacements should all be considered as falling within the protection scope of this application.

1. A display panel, comprising:
a first substrate;
a metal layer, the metal layer being arranged on the first substrate;
the metal layer comprising an electrical contact area electrically connected to a corresponding conductive component; and
a protective layer, covering the metal layer and keeping away from the electrical contact area.

2. The display panel according to claim 1, wherein the protective layer comprises a first protective layer and a second protective layer; and
the electrical contact area is provided on an upper surface of the metal layer, and the width of the electrical contact area is less than the width of the metal layer; and the first protective layer and the second protective layer are respectively arranged at two ends of the metal layer, and parts of the first protective layer and the second protective layer cover the upper surface of the metal layer and correspond to positions of the end parts of the electrical contact area.

3. The display panel according to claim 1, wherein the protective layer comprises a third protective layer and a fourth protective layer; and
the electrical contact area is provided on an upper surface of the metal layer, and the width of the electrical contact area is less than the width of the metal layer; and the third protective layer and the fourth protective layer are respectively arranged on two ends of the metal layer.

4. The display panel according to claim 1, wherein the protective layer and a planarizing layer are of a same material.

5. The display panel according to claim 1, wherein the metal layer comprises aluminum.

6. The display panel according to claim 1, wherein the metal layer comprises copper.

7. The display panel according to claim 1, herein the metal layer comprises silver.

8. The display panel according to claim 1, wherein the metal layer is fully covered by the protective layer except the electrical contact area.

9. The display panel according to claim 1, wherein the first substrate is an array substrate.

10. A display panel, comprising:
a first substrate;
a metal layer, the metal layer being arranged on the first substrate;
the metal layer comprising an electrical contact area electrically connected to a corresponding conductive component; and
a protective layer, covering the metal layer and keeping away from the electrical contact area, wherein
the protective layer comprises a first protective layer and a second protective layer; and
the electrical contact area is provided on an upper surface of the metal layer, and the width of the electrical contact area is less than the width of the metal layer; and the first protective layer and the second protective layer are respectively arranged at two ends of the metal layer, parts of the first protective layer and the second protective layer cover the upper surface of the metal layer and correspond to positions of the end parts of the electrical contact area, the protective layer and a planarizing layer are of a same material, and the metal layer comprises aluminum.

11. A method adapted to manufacture a display panel, steps of the method adapted to manufacture a display panel comprising:
forming a metal layer on a first substrate; and
forming a protective layer on the metal layer, wherein
the metal layer comprises an electrical contact area electrically connected to a corresponding conductive component: and the protective layer keeps away from the electrical contact area.

12. The method adapted to manufacture a display panel according to claim 11, wherein the step of forming a protective layer on the metal layer comprises:
coating a protective layer material on the metal layer;
exposing the electrical contact area and an area corresponding to the protective layer by using a semi-transparent mask; and
forming the protective layer after development, wherein
the light transmittance of the semi-transparent mask corresponding to the electrical contact area is greater than the light transmittance of an area corresponding to the protective layer.

13. The method adapted to manufacture a display panel according to claim 11, wherein the light transmittances of two end parts of the electrical contact area are 20% to 30%.

14. The method adapted to manufacture a display panel according to claim 11, wherein the protective layer comprises a first protective layer and a second protective layer; and
the electrical contact area is provided on an upper surface of the metal layer, and the width of the electrical contact area is less than the width of the metal layer; and the first protective layer and the second protective layer are respectively arranged on two ends of the metal layer and at positions of two end parts of the metal layer.

15. The method adapted to manufacture a display panel according to claim 11, wherein the transmittance of the electrical contact area is 80% to 100%.

16. The method adapted to manufacture a display panel according to claim 11, wherein the semi-transparent mask comprises:
a fully transparent area, the fully transparent area corresponding to the electrical contact area of the metal layer; and
a semi-transparent area, the semi-transparent area corresponding to two end parts of the metal layer.

17. The method adapted to manufacture a display panel according to claim 16, wherein the semi-transparent area and the fully transparent area are in a same line.
